(19) United States
(12) Patent Application Publication
(10) Pub. No.: US 2026/0211017 A1
(43) Pub. Date: Jul. 23, 2026

(54) METHOD AND SYSTEM FOR MEASURING FREQUENCY CHARACTERISTIC OF CAPACITOR VOLTAGE TRANSFORMER, AND TERMINAL

(71) Applicant: Sichuan University, Chengdu City (CN)

(72) Inventors: Fangwei XU, Chengdu City (CN); Tongyu LIU, Chengdu City (CN); Qin SHU, Chengdu City (CN); Zhe CHEN, Chengdu City (CN); Shixi LIN, Chengdu City (CN); Jianyou YANG, Chengdu City (CN); Yongli YI, Chengdu City (CN); Zhe WANG, Chengdu City (CN); Wei LI, Chengdu City (CN); Hang MENG, Chengdu City (CN); Yizhi SHI, Chengdu City (CN); Liyuan CHEN, Chengdu City (CN)

(21) Appl. No.: 19/446,352

(22) Filed: Jan. 12, 2026

(30) Foreign Application Priority Data
Jan. 21, 2025 (CN) 202510090385.3

(51) Int. Cl. G01R 23/16; G01R 31/62

(52) U.S. Cl. CPC G01R 23/16; G01R 31/62

(57) ABSTRACT

The present disclosure discloses a method and system for measuring a frequency characteristic of a capacitor voltage transformer, and a terminal. The technical solutions are: collecting, with a transient voltage of a power system as an excitation voltage on a primary side of the CVT, a response of a secondary side of the CVT to the transient voltage, to obtain a transient voltage response; performing spectrum analysis on the transient voltage response, identifying a valley point and a peak point, and extracting a valley frequency corresponding to the valley point and a peak frequency corresponding to the peak point; and calculating a stray parameter of the CVT according to the valley frequency and/or the peak frequency, to obtain a frequency characteristic measurement result. According to the present disclosure, online measurement of the frequency response characteristic of the CVT can be implemented.

### CROSS-REFERENCE TO RELATED APPLICATION

This application claims the benefit of Chinese Patent Application No. 202510090385.3, filed Jan. 21, 2025, which is hereby incorporated by reference in its entirety including any tables, figures, or drawings.

### TECHNICAL FIELD

The present disclosure relates to the technical field of voltage transformers, and specifically, to a method and system for measuring a frequency characteristic of a capacitor voltage transformer, and a terminal.

### BACKGROUND

A frequency characteristic of a capacitor voltage transformer (CVT) is very important for harmonic measurement of a power system. Due to nonlinear impedance and inherent capacitance of the CVT, ferromagnetic resonance sometimes occurs in the CVT. Therefore, a damping device needs to be used to suppress resonance. In addition, a harmonic transfer characteristic of the CVT at a high frequency may be affected by stray capacitance, which needs to be considered in design and application.

Currently, methods for measuring a frequency response characteristic of a CVT mainly include an intrusive method and a non-intrusive method. In the intrusive method, an excitation voltage such as a sine signal and a pulse signal is applied to a primary side of the CVT, and a response of a secondary side of the CVT is synchronously measured, to calculate the frequency response characteristic of the CVT. The intrusive method needs to disconnect the CVT from a power grid, which is usually performed during power outage maintenance of the CVT. However, this cannot be always implemented in engineering. In the non-intrusive method, a standard voltage transformer whose frequency characteristic is known and a to-be-tested CVT are connected in parallel to a same voltage bus, and a frequency characteristic of the to-be-tested CVT is calculated by comparing voltages on secondary sides of the standard voltage transformer and the to-be-tested CVT. However, in this method, each CVT needs to be connected in parallel to the standard transformer before measurement can be performed, resulting in cumbersome operations and a low frequency resolution.

Therefore, how to research and design a method and system for measuring a frequency characteristic of a capacitor voltage transformer, and a terminal that can overcome the above-mentioned shortcomings is an urgent problem to be solved currently.

### SUMMARY

To solve the disadvantages in the conventional technology, an objective of the present disclosure is to provide a method and system for measuring a frequency characteristic of a capacitor voltage transformer, and a terminal, to implement online measurement of a frequency response characteristic of the CVT.

The above-mentioned technical objective of the present disclosure is achieved by the following technical solutions.

According to a first aspect, a method for measuring a frequency characteristic of a capacitor voltage transformer is provided, including the following steps of:
collecting, with a transient voltage of a power system as an excitation voltage on a primary side of the CVT, a response of a secondary side of the CVT to the transient voltage, to obtain a transient voltage response;
performing spectrum analysis on the transient voltage response, identifying a valley point and a peak point, and extracting a valley frequency corresponding to the valley point and a peak frequency corresponding to the peak point; and
calculating a stray parameter of the CVT according to the valley frequency and/or the peak frequency, to obtain a frequency characteristic measurement result.

Further, the transient voltage is any one of a voltage sag process voltage, a voltage swell process voltage, a switching overvoltage, and a lightning overvoltage.

Further, a process of calculating the stray parameter specifically includes:
establishing an equivalent circuit that takes into account the stray parameter of the CVT;
simplifying the CVT according to an RL-C parallel branch to obtain a simplified circuit;
establishing an expression for solving impedance of each part in the simplified circuit;
establishing a solution model for the stray parameter with reference to the expression for solving impedance of a corresponding part, with the simplified circuit regarded as a cascade of two subsystems; and
inputting the valley frequency and/or the peak frequency to the solution model, to obtain the stray parameter of the CVT by calculation.

Further, the stray parameter includes stray capacitance of a compensation reactor, ground stray capacitance of a primary winding of an intermediate transformer, ground stray capacitance of a secondary winding of the intermediate transformer, and distributed capacitance between primary and secondary windings.

Further, if the stray parameter is the stray capacitance of the compensation reactor, an expression of the solution model is:

$${{F}_{1}^{′} ( ω ) \vert}_{ω = {ω}_{min \_ 1}} = 0 , {ω}_{min \_ 1} = 2 π {f}_{min \_ 1} ,$$

where F₁′(ω)| denotes a derivative function of |Z₁| with respect to an angular frequency ω; ω_{min_1} denotes an angular frequency corresponding to a first valley point; f_{min_1} denotes a valley frequency corresponding to the first valley point; and Z₁ denotes impedance corresponding to the stray capacitance of the compensation reactor.

Further, if the stray parameter is the distributed capacitance between the primary and secondary windings, the expression of the solution model is:

$${{F}_{2}^{′} ( ω ) \vert}_{ω = {ω}_{min \_ 2}} = 0 , {ω}_{min \_ 2} = 2 π {f}_{min \_ 2} ,$$

where F₂′(ω) denotes a derivative function of |Z₂| with respect to an angular frequency ω; ω_{min_2} denotes an angular frequency corresponding to a second valley point, f_{min_2} denotes a valley frequency corresponding to the second valley point; and Z₂ denotes impedance corresponding to the distributed capacitance between the primary and secondary windings.

Further, if the stray parameter is the ground stray capacitance of the primary winding of the intermediate transformer and/or the ground stray capacitance of the secondary winding of the intermediate transformer, the expression of the solution model is:

$$\{ \begin{matrix}{{F}_{3}^{′} ( ω ) \vert}_{ω = {ω}_{max \_ 1}} = 0 , {ω}_{max \_ 1} = 2 π {f}_{max \_ 1} \\ {{F}_{3}^{′} ( ω ) \vert}_{ω = {ω}_{max \_ 2}} = 0 , {ω}_{max \_ 2} = 2 π {f}_{max \_ 2}\end{matrix} ,$$

$${Z}_{X} = {Z}_{Ce} + {Z}_{1} + {Z}_{Cp} // ( {Z}_{2} + {Z}_{3} )$$

where F₃′(ω) denotes a derivative function of |Zₓ| with respect to an angular frequency ω; ω_{max_1} denotes an angular frequency corresponding to a first peak point; ω_{max_2} denotes an angular frequency corresponding to a second peak point; f_{max_1} denotes a peak frequency corresponding to the first peak point; f_{max_2} denotes a peak frequency corresponding to the second peak point; Z_{Ce} denotes capacitive reactance corresponding to the ground stray capacitance of the primary winding of the intermediate transformer; Z_{Cp} denotes capacitive reactance corresponding to the ground stray capacitance of the secondary winding of the intermediate transformer; Z₁ denotes impedance corresponding to the stray capacitance of the compensation reactor; Z₂ denotes impedance corresponding to the distributed capacitance between the primary and secondary windings; Z₃ denotes impedance corresponding to the ground stray capacitance of the secondary winding of the intermediate transformer; and // denotes parallel connection.

According to a second aspect, a system for measuring a frequency characteristic of a capacitor voltage transformer is provided, including:
a response collection module, configured to collect, with a transient voltage of a power system as an excitation voltage on a primary side of the CVT, a response of a secondary side of the CVT to the transient voltage, to obtain a transient voltage response;
a spectrum analysis module, configured to perform spectrum analysis on the transient voltage response, identify a valley point and a peak point, and extract a valley frequency corresponding to the valley point and a peak frequency corresponding to the peak point; and
a parameter calculation module, configured to calculate a stray parameter of the CVT according to the valley frequency and/or the peak frequency, to obtain a frequency characteristic measurement result.

According to a third aspect, a computer terminal is provided, including a memory, a processor, and a computer program stored in the memory and executable on the processor, where the processor, when executing the program, implements the method for measuring a frequency characteristic of a capacitor voltage transformer according to any one of the implementations of the first aspect.

According to a fourth aspect, a computer-readable medium, where a computer program is stored on the computer-readable medium, and the computer program, when executed by a processor, implements the method for measuring a frequency characteristic of a capacitor voltage transformer according to any one of the implementations of the first aspect.

Compared with the conventional technology, the present disclosure has the following beneficial effects:

1. In the method for measuring a frequency characteristic of a capacitor voltage transformer according to the present disclosure, online measurement of the frequency response characteristic of the CVT can be implemented.

2. According to the present disclosure, there is no need to apply an excitation voltage to the primary side of the CVT or measure a primary voltage of the CVT, without interfering with an apparatus and the system.

3. According to the present disclosure, the frequency characteristic of the CVT is analyzed by using a transient process of a power network, required data can be obtained with low difficulty, and there is a sufficient data volume.

4. The frequency response characteristic of the CVT designed in the present disclosure and an analytical form of a unit impulse response do not need to be fitted, thereby achieving higher accuracy.

### BRIEF DESCRIPTION OF DRAWINGS

The accompanying drawings described herein are used to provide a further understanding of embodiments of the present disclosure, and constitute a part of the present disclosure, but do not constitute limitations on the embodiments of the present disclosure. In the accompanying drawings:

FIG. 1 is an equivalent circuit diagram taking into account stray capacitance of a CVT according to Embodiment 1 of the present disclosure;

FIG. 2 is a curve graph of an amplitude-frequency characteristic of a typical CVT according to Embodiment 1 of the present disclosure;

FIG. 3 is a diagram of an RL-C parallel branch according to Embodiment 1 of the present disclosure;

FIG. 4 is a diagram of a simplified circuit of the CVT according to Embodiment 1 of the present disclosure;

FIG. 5 is a waveform diagram of an overvoltage measured by the CVT according to Embodiment 1 of the present disclosure;

FIG. 6 is a spectrum diagram of the overvoltage measured by the CVT according to Embodiment 1 of the present disclosure; and

FIG. 7 is a block diagram of a system according to Embodiment 2 of the present disclosure.

### DETAILED DESCRIPTION

To make the objectives, technical solutions, and advantages of the present disclosure clearer, the present disclosure is further described in detail below with reference to embodiments and the accompanying drawing. The schematic implementations of the present disclosure and descriptions thereof are only used to explain the present disclosure, but are not intended to limit the present disclosure.

Embodiment 1: A method for measuring a frequency characteristic of a capacitor voltage transformer is provided. The method implements online measurement of a frequency response characteristic of the CVT, and includes the following steps:

S1: Collect, with a transient voltage of a power system as an excitation voltage on a primary side of the CVT, a response of a secondary side of the CVT to the transient voltage, to obtain a transient voltage response.

S2: Perform spectrum analysis on the transient voltage response, identify a valley point and a peak point, and extract a valley frequency corresponding to the valley point and a peak frequency corresponding to the peak point.

S3: Calculate a stray parameter of the CVT according to the valley frequency and/or the peak frequency, to obtain a frequency characteristic measurement result.

Design parameters of the CVT structure (parameters of a capacitive voltage divider, a compensation reactor, an intermediate transformer, and the like) are all known quantities, and all the stray parameters have been obtained. Therefore, the frequency characteristic of the CVT can be obtained by calculation in combination with an equivalent circuit of the CVT.

In step S1, the transient voltage is any one of a voltage sag process voltage, a voltage swell process voltage, a switching overvoltage, and a lightning overvoltage, and the lightning overvoltage refers to a case where its peak value does not exceed a saturation voltage of the CVT.

The frequency response characteristic of the CVT and voltages on the primary side and the secondary side of the CVT meet the following relationship in frequency domain:

$$Y ( ω ) = X ( ω ) \cdot H ( ω ) ,$$

where H(ω) is the frequency response characteristic of the CVT, X(ω) and Y(ω) are voltage frequency spectra of the primary side and the secondary side of the CVT respectively, and w is an angular frequency.

H(ω) generally has zeros and poles, which are represented as valley and peak points on an amplitude-frequency characteristic |H(ω)| curve. FIG. 2 shows an amplitude-frequency curve of a typical CVT, and it can be seen that the curve has two peak points and two valley points corresponding to frequencies f_{max_1} and f_{max_2} (peak frequencies), and f_{min_1} and f_{min_2} (valley frequencies), respectively. If the secondary side voltage frequency spectrum Y(ω) of the CVT is required to have the same zeros and poles as the frequency characteristic H(ω) of the CVT, namely valley and peak frequencies, X(ω) should meet the following requirements:

(1) X(ω) should have a frequency spectrum range covering the zeros and poles of H(ω).

(2) Values of X(ω) at the zeros and poles of H(ω) should be non-zero constants, but cannot be the zeros and poles, so as to avoid cancellation with the zeros and poles of H(ω).

A unit pulse voltage meets the foregoing condition. As an excitation voltage on the primary side of the CVT, the unit pulse voltage can excite the secondary side of the CVT to output a broadband response. A frequency spectrum of the response forms a peak value and a valley value at the peak and valley frequencies of the CVT. However, it is difficult to apply pulse excitation to the online CVT on the project site, and interference is caused to the power system, which is not conducive to the stable operation of the system. Therefore, a method for calculating a stray parameter by observing a transient response frequency spectrum feature of a CVT with a transient voltage of the power system as excitation is proposed. A specific derivation is as follows.

The following formula provides an empirical relationship between a time of a rising edge or a falling edge of a signal and an effective bandwidth of the signal: A shorter rise time or fall time of the signal indicates richer frequency components, namely a wider bandwidth.

$${B}_{W} \approx \frac{0.35}{{R}_{T}} ,$$

where B_{W} is an effective bandwidth, and R_{T} is a time of the rising or falling edge.

For example, the effective bandwidth of an overvoltage with a rise time of 17.5 μs can reach 20 kHz, which can cover valley and peak frequencies of a general CVT, and meet requirements for a harmonic measurement frequency range in engineering.

A double exponential overvoltage is used as an example, and a time domain and a frequency domain of the double exponential overvoltage are respectively.

$${U}_{m} ( {e}^{- α t} - {e}^{- β t} ) ↔ {U}_{m} ( \frac{1}{α + j ω} - \frac{1}{β + j ω} ) ,$$

where Um is an overvoltage peak value, and α and β are waveform control parameters; j denotes an imaginary number; and t denotes a time.

It can be seen that a frequency range and a frequency spectrum characteristic of the double exponential overvoltage meet a condition for exciting the CVT to generate a valley and peak response, that is, the frequency domain is relatively wide and there is no valley or peak value at the valley and peak frequencies of the CVT. Other typical overvoltages, such as a Heidler-type overvoltage and a pulse overvoltage, also have similar characteristics.

In addition to the switching overvoltage, a sag voltage, a swell voltage, and the like caused by a ground short-circuit fault in engineering also meet the above-mentioned properties. That is, a transient signal commonly used in engineering can be used to excite the CVT to generate a frequency response in a broadband domain, and the stray parameter and the frequency response characteristic of the CVT are calculated according to the peak and valley frequencies in the response frequency spectrum.

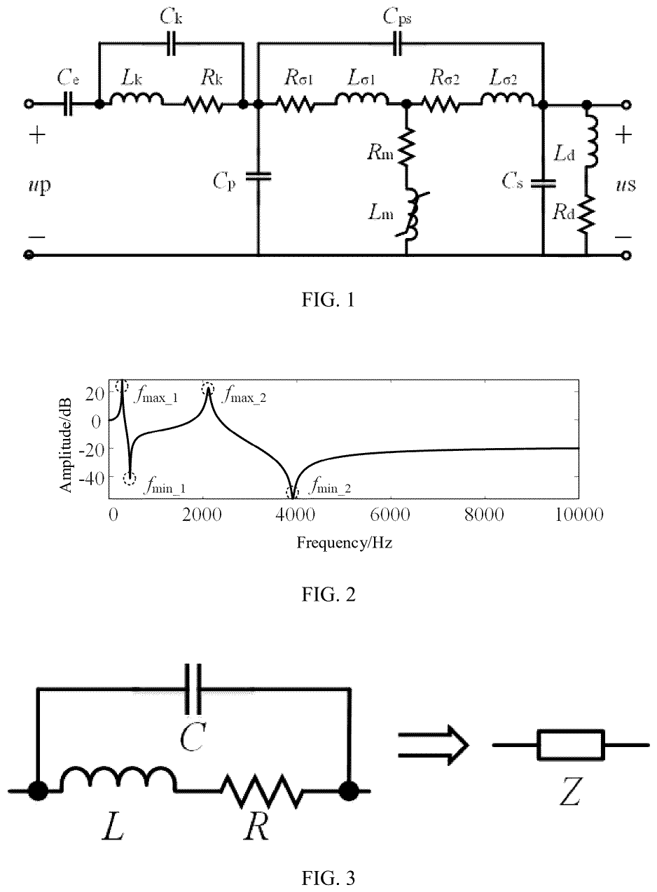

In step S2, as shown in FIG. 1, internal structure parameters of the CVT fall into design parameters and stray parameters. The design parameters are known parameters designed by a manufacturer. These parameters include an equivalent capacitance parameter Ce of the capacitive voltage divider, impedance parameters Rₖ and Lₖ of the compensation reactor, impedance parameters R_{σ1}, L_{σ1}, R_{σ2}, and L_{σ2} of primary and secondary windings of the intermediate transformer, impedance parameters Lₘ and Rₘ of an excitation winding, and impedance parameters R_{d} and L_{d} of a damper. Cₖ denotes stray distributed capacitance of the compensation reactor. up denotes a primary voltage, and us denotes a secondary voltage.

The stray parameters are difficult to measure and have significant individual differences, and are main reasons why different CVTs differ in frequency response characteristics. These parameters include stray capacitance of the compensation reactor, ground stray capacitance Cₚ and Cₛ of primary and secondary windings of the intermediate transformer, and distributed capacitance Cₚₛ between the primary and secondary windings.

A principle of forming the frequencies f_{max_1} and f_{max_2} (peak frequencies), and f_{min_1} and f_{min_2}(valley frequencies) in the amplitude-frequency curve of the typical CVT shown in FIG. 2 is as follows:

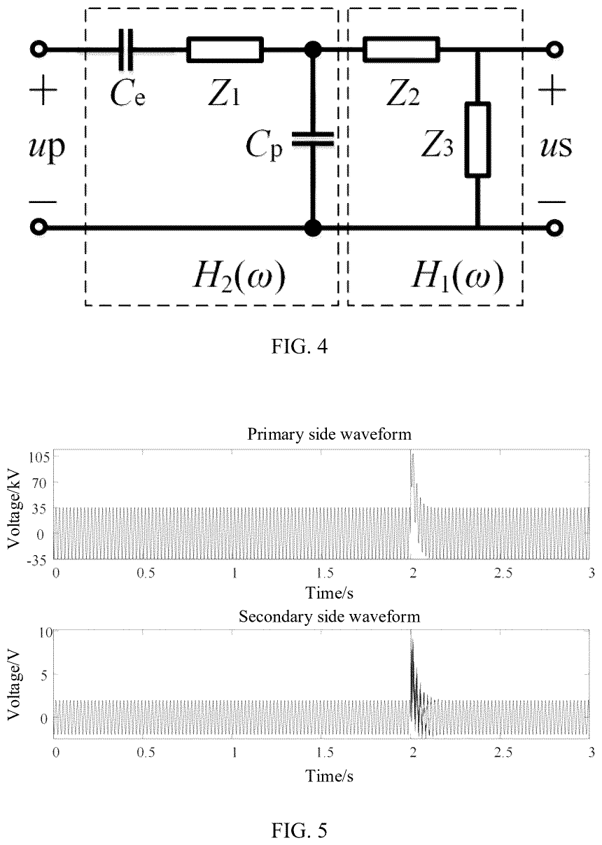

First, the CVT is simplified according to an RL-C parallel branch (as shown in FIG. 3) to obtain a simplified circuit. As shown in FIG. 4, impedance of each part is in the following formula:

$$\{ \begin{matrix}{Z}_{1} = ( {R}_{k} + j ω {L}_{k} ) // ( \frac{1}{j ω {C}_{k}} ) \\ {Z}_{2} = ( {R}_{σ} + j ω {L}_{σ} ) // ( \frac{1}{j ω {C}_{p s}} ) \\ {Z}_{3} = ( {R}_{d} + j ω {L}_{d} ) // ( \frac{1}{j ω {C}_{s}} )\end{matrix} ,$$

where // denotes parallel connection, and R_{σ} and L_{σ} are respectively total winding resistance and leakage reactance that are converted to the primary side of the transformer.

Then, the CVT may be seen as a cascading form of two subsystems, as shown in FIG. 4:

$$H ( ω ) = {H}_{1} ( ω ) \cdot {H}_{2} ( ω )$$

If

$$\frac{1}{j ω {C}_{p}} and \frac{1}{j ω {C}_{e}}$$

are denoted as Z_{Cp} and Z_{Ce} respectively,

$$\{ \begin{matrix}{H}_{1} ( ω ) = \frac{{Z}_{3}}{{Z}_{2} + {Z}_{3}} \\ {H}_{2} ( ω ) = \frac{{Z}_{Cp} // ( {Z}_{2} + {Z}_{3} )}{{Z}_{Ce} + {Z}_{1} + {Z}_{Cp} // ( {Z}_{2} + {Z}_{3} )}\end{matrix} .$$

It can be learned from the foregoing formula that, when |Z₁| and |Z₂| each reach a maximum value, amplitudes of a first subsystem H₁(ω) and a second subsystem H₂(ω) tend to minimum values, that is, the amplitudes are denoted as valley points in the amplitude-frequency characteristic curve of the CVT, for example, amplitude-frequency characteristics corresponding to f_{min_1} and f_{min_2} in FIG. 2.

$${lim}_{\vert {Z}_{2} \vert \to max} \vert \frac{{Z}_{3}}{{Z}_{2} + {Z}_{3}} \vert \to Minimum ; and$$

$${lim}_{\vert {Z}_{2} \vert \to max} \vert \frac{{Z}_{Cp} // ( {Z}_{2} + {Z}_{3} )}{{Z}_{Ce} + {Z}_{1} + {Z}_{Cp} // ( {Z}_{2} + {Z}_{3} )} \vert \to Minimum ,$$

where Minimum is a minimum value of

$$\vert \frac{{Z}_{Cp} // ( {Z}_{2} + {Z}_{3} )}{{Z}_{Ce} + {Z}_{1} + {Z}_{Cp} // ( {Z}_{2} + {Z}_{3} )} \vert .$$

Because a denominator Z₂+Z₃ in H₁(ω) and Z₂+Z₃ in a numerator of H₂(ω) cancel out, a maximum value (denoted as amplitude-frequency characteristics corresponding to f_{max_1} and f_{max_2} in FIG. 2) of an H(ω) amplitude corresponding to the CVT depends on a minimum value of a denominator in H₂(ω):

$${lim}_{\vert {Z}_{x} \vert \to min} \vert H ( ω ) \vert \to Maximum ,$$

where Zₓ is the denominator of H₂(ω), namely Zₓ=Z_{Ce}+Z₁+Z_{Cp}//(Z₂+Z₃), and Maximum is the maximum value of |H(ω)|.

In conclusion, it can be concluded that the valley frequencies f_{min_1} and f_{min_2} of H (ω) are only related to Cₖ and Cₚₛ. When Cₖ or Cₚₛ is fixed but other stray capacitance changes, the valley frequencies f_{min_1} and f_{min_2} remain unchanged. The peak frequencies f_{max_1} and f_{max_2} of H(ω) are related to all the stray parameters. When any stray parameter changes, the peak frequencies f_{max_1} and f_{max_2} are shifted to different degrees.

In step S3, under the condition that only part of information (peak and valley frequencies), namely f_{max_1}, f_{max_2}, f_{min_1}, and f_{min_2}, of H(ω) is known, but specific amplitudes and phases corresponding to these frequencies are not known, by using a characteristic that the valley frequency f_{min_1} and f_{min_2} are respectively stationary points of |Z₁| and |Z₂|, first, Cₖ is solved by using a univariate equation with respect to Cₖ; and Cₚₛ is solved by using a univariate equation with respect to Cₚₛ, as shown in the following formulae:

$${{F}_{1}^{′} ( ω ) \vert}_{ω = {ω}_{min \_ 1}} = 0$$

$${{F}_{2}^{′} ( ω ) \vert}_{ω = {ω}_{min \_ 2}} = 0 ,$$

where F₁′(ω) and F₂′(ω) are respectively derivative functions of |Z₁| and |Z₂| with respect to ω, ω_{min_1}=2πf_{min_1}, and ω_{min_2}=2πf_{min_2}.

Then, by using a characteristic that the peak frequencies f_{max_1} and f_{max_2} are respectively stationary points of |Zₓ|, Cₚₛ and Cₛ may be simultaneously solved by using the equation set shown as follows:

$$\{ \begin{matrix}{{F}_{3}^{′} ( ω ) \vert}_{ω = {ω}_{max \_ 1}} = 0 \\ {{F}_{3}^{′} ( ω ) \vert}_{ω = {ω}_{max \_ 2}} = 0\end{matrix} ,$$

where F₃′(ω) is a derivative coefficient of |Zₓ| with respect to ω,

$${ω}_{max \_ 1} = 2 π {f}_{max \_ 1} , and {ω}_{min \_ 2} = 2 π {f}_{min \_ 2} .$$

It should be noted that although F_{Zx}′ is a multivariate function for all stray parameters, since Cₚₛ and Cₖ have been obtained respectively by using the valley frequencies of the formula, the foregoing equation set is a bivariate equation set with respect to Cₚ and Cₛ.

For example, a CVT frequency response characteristic test system is built up by combination with PSCAD and MATLAB simulation platforms. After the CVT runs normally for 2s, a lightning overvoltage is added to a line, and a line voltage and a measured voltage on the secondary side of the CVT are recorded synchronously, as shown in FIG. 5.

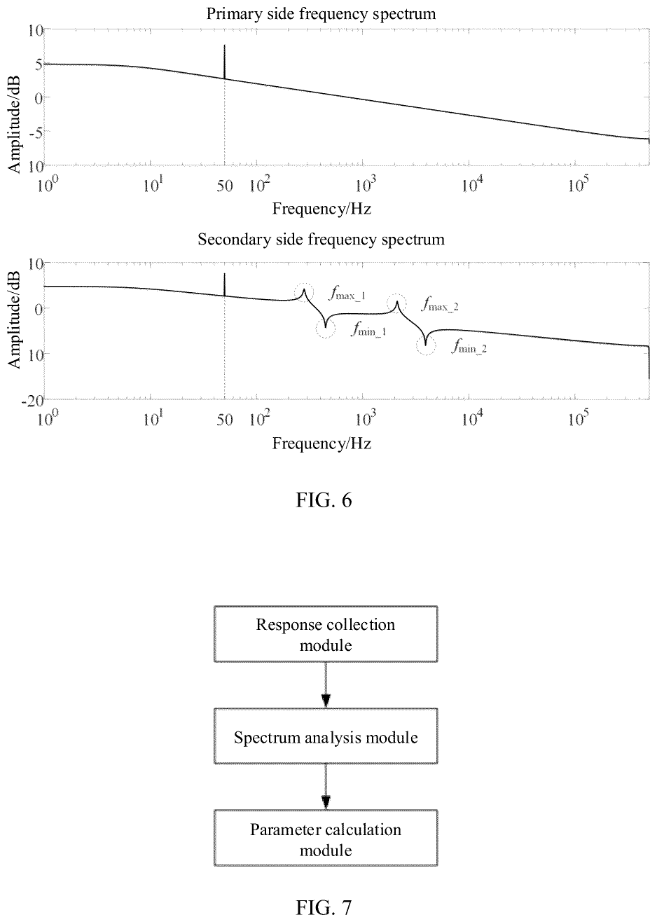

The frequency spectrum of the voltage measured by the CVT forms peak values at f_{max_1}=252 Hz and f_{max_2}=2117 Hz, and forms valley values at f_{min_1}=448 Hz and f_{min_2}=3856 Hz, as shown in FIG. 6. According to the principle of first calculating Cₖ and Cₚₛ by using the valley frequencies, and then calculating ground stray capacitance Cₚ and Cₛ of the primary and secondary windings by using the valley/peak frequencies, relative error between the stray capacitance parameters and theoretical true values thereof are respectively Cₖ=774.12 pF (relative error: 0.75%); Cₚₛ=201.15 pF (relative error: 0.58%); Cₛ=991.65 pF (relative error: 0.84%); and Cₚ=200.45 pF (relative error: 0.22%). Therefore, it can be believed that the proposed method can accurately identify the valley/peak values from the transient response of the CVT and calculate the stray parameters.

Embodiment 2: A system for measuring a frequency characteristic of a capacitor voltage transformer is provided. The system is configured to implement the method for measuring a frequency characteristic of a capacitor voltage transformer that is described in Embodiment 1. As shown in FIG. 7, the system includes a response collection module, a spectrum analysis module, and a parameter calculation module.

The response collection module is configured to collect, with a transient voltage of a power system as an excitation voltage on a primary side of the CVT, a response of a secondary side of the CVT to the transient voltage, to obtain a transient voltage response; the spectrum analysis module is configured to perform spectrum analysis on the transient voltage response, identify a valley point and a peak point, and extract a valley frequency corresponding to the valley point and a peak frequency corresponding to the peak point; and the parameter calculation module, configured to calculate a stray parameter of the CVT according to the valley frequency and/or the peak frequency, to obtain a frequency characteristic measurement result.

The present disclosure further provides a computer terminal, including a memory, a processor, and a computer program stored in the memory and executable on the processor, where the processor, when executing the program, implements the method for measuring a frequency characteristic of a capacitor voltage transformer that is described in Embodiment 1.

The present disclosure further provides a computer-readable medium, where a computer program is stored on the computer-readable medium, and the computer program, when executed by a processor, implements the method for measuring a frequency characteristic of a capacitor voltage transformer that is described in Embodiment 1.

Working principle: In the method for measuring a frequency characteristic of a capacitor voltage transformer according to the present disclosure, online measurement of the frequency response characteristic of the CVT can be implemented. According to the present disclosure, there is no need to apply an excitation voltage to the primary side of the CVT or measure a primary voltage of the CVT, without interfering with an apparatus and the system. According to the present disclosure, the frequency characteristic of the CVT is analyzed by using a transient process of a power network, required data can be obtained with low difficulty, and there is a sufficient data volume. The frequency response characteristic of the CVT designed in the present disclosure and an analytical form of a unit impulse response do not need to be fitted, thereby achieving higher accuracy.

A person skilled in the art should understand that the embodiments of the present application can be provided as methods, systems, or computer program products. Therefore, the present application can use a form of hardware only embodiments, software only embodiments, or embodiments with a combination of software and hardware. In addition, the present application can use a form of a computer program product that is implemented on one or more computer-usable storage media (including but not limited to a disk storage, a CD-ROM, an optical storage, or the like) that include computer-usable program code.

The present application is described with reference to flowcharts and/or block diagrams of a method, an apparatus (system), and a computer program product according to embodiments of the present application. It should be understood that computer program instructions can be used to implement each procedure and/or each block in the flowcharts and/or the block diagrams and a combination of procedures and/or blocks in the flowcharts and/or the block diagrams. These computer program instructions can be provided for a general-purpose computer, a dedicated computer, an embedded processor, or a processor of another programmable data processing device to generate a machine, so that the instructions executed by the computer or the processor of the another programmable data processing device generate an apparatus for implementing a specified function in one or more procedures in the flowcharts and/or in one or more blocks in the block diagrams.

These computer program instructions can alternatively be stored in a computer-readable memory that can instruct a computer or another programmable data processing device to work in a specific way, so that an instruction stored in the computer-readable memory generates an artifact including an instruction apparatus, and the instruction apparatus implements a specified function in one or more procedures in the flowcharts and/or one or more blocks in the block diagrams.

Alternatively, these computer program instructions can be loaded onto a computer or another programmable data processing apparatus, so that a series of operations and steps are performed on the computer or the another programmable apparatus, to generate computer-implemented processing. Therefore, the instructions executed on the computer or the another programmable apparatus provide steps for implementing a specific function in one or more procedures in the flowcharts and/or in one or more blocks in the block diagrams.

The objectives, technical solutions, and beneficial effects of the present disclosure are further described in detail in the above specific implementations. It should be understood that the above described are only specific implementations of the present disclosure and are not intended to limit the protection scope of the present disclosure. Any modification, equivalent replacement, improvement, and the like made within the spirit and principle of the present disclosure should fall within the protection scope of the present disclosure.

1. A method for measuring a frequency characteristic of a capacitor voltage transformer (CVT), comprising:
collecting, with a transient voltage of a power system as an excitation voltage on a primary side of the CVT, a response of a secondary side of the CVT to the transient voltage, to obtain a transient voltage response;
performing spectrum analysis on the transient voltage response, identifying a valley point and a peak point, and extracting a valley frequency corresponding to the valley point and a peak frequency corresponding to the peak point; and
calculating a stray parameter of the CVT according to the valley frequency and/or the peak frequency, to obtain a frequency characteristic measurement result, wherein a process of calculating the stray parameter specifically comprises:
establishing an equivalent circuit that takes into account the stray parameter of the CVT;
simplifying the CVT according to an RL-C parallel branch to obtain a simplified circuit; establishing an expression for solving impedance of each part in the simplified circuit;
establishing a solution model for the stray parameter with reference to the expression for solving impedance of a corresponding part, with the simplified circuit regarded as a cascade of two subsystems, wherein if the stray parameter is stray capacitance of a compensation reactor, an expression of the solution model is:
$${{F}_{1}^{′} ( ω ) \vert}_{ω = {ω}_{min \_ 1}} = 0 , {ω}_{min \_ 1} = 2 π {f}_{min \_ 1} ,$$
wherein F₁′(ω) denotes a derivative function of |Z₁| with respect to an angular frequency ω; ω_{min_1} denotes an angular frequency corresponding to a first valley point; f_{min_1} denotes a valley frequency corresponding to the first valley point; Z₁ denotes impedance corresponding to the stray capacitance of the compensation reactor; if the stray parameter is distributed capacitance between primary and secondary windings, the expression of the solution model is:
$${{F}_{2}^{′} ( ω ) \vert}_{ω = {ω}_{min \_ 2}} = 0 , {ω}_{min \_ 2} = 2 π {f}_{min \_ 2} ,$$
wherein F₂′(ω) denotes a derivative function of |Z₂| with respect to an angular frequency ω; ω_{min_2} denotes an angular frequency corresponding to a second valley point; f_{min_2} denotes a valley frequency corresponding to the second valley point; Z₂ denotes impedance corresponding to the distributed capacitance between the primary and secondary windings; if the stray parameter is ground stray capacitance of a primary winding of an intermediate transformer and/or ground stray capacitance of a secondary winding of the intermediate transformer the expression of the solution model is:
$$\{ \begin{matrix}{{F}_{3}^{′} ( ω ) \vert}_{ω = {ω}_{max \_ 1}} = 0 , {ω}_{max \_ 1} = 2 π {f}_{max \_ 1} \\ {{F}_{3}^{′} ( ω ) \vert}_{ω = {ω}_{max \_ 2}} = 0 , {ω}_{max \_ 2} = 2 π {f}_{max \_ 2}\end{matrix}$$
$${Z}_{X} = {Z}_{Ce} + {Z}_{1} + {Z}_{Cp} // ( {Z}_{2} + {Z}_{3} )$$
wherein F₃′(ω) denotes a derivative function of |Zₖ| with respect to an angular frequency ω; ω_{max_1} denotes an angular frequency corresponding to a first peak point; ω_{max_2} denotes an angular frequency corresponding to a second peak point; f_{max_1} denotes a peak frequency corresponding to the first peak point; f_{max_2} denotes a peak frequency corresponding to a second peak point; Z_{Ce} denotes capacitive reactance corresponding to the ground stray capacitance of the primary winding of the intermediate transformer; Z_{Cp} denotes capacitive reactance corresponding to the ground stray capacitance of the secondary winding of the intermediate transformer; Z₁ denotes impedance corresponding to the stray capacitance of the compensation reactor; Z₂ denotes impedance corresponding to the distributed capacitance between the primary and secondary windings; Z₃ denotes impedance corresponding to the ground stray capacitance of the secondary winding of the intermediate transformer; and // denotes parallel connection; and
inputting the valley frequency and/or the peak frequency to the solution model, to obtain the stray parameter of the CVT by calculation.

2. The method for measuring a frequency characteristic of a capacitor voltage transformer according to claim 1, wherein the transient voltage is any one of a voltage sag process voltage, a voltage swell process voltage, a switching overvoltage, and a lightning overvoltage.

3. The method for measuring a frequency characteristic of a capacitor voltage transformer according to claim 2, wherein the stray parameter comprises the stray capacitance of the compensation reactor, the ground stray capacitance of the primary winding of the intermediate transformer, the ground stray capacitance of the secondary winding of the intermediate transformer, and the distributed capacitance between the primary and secondary windings.

4. A system for measuring a frequency characteristic of a capacitor voltage transformer, comprising:
a response collection module, configured to collect, with a transient voltage of a power system as an excitation voltage on a primary side of the CVT, a response of a secondary side of the CVT to the transient voltage, to obtain a transient voltage response;
a spectrum analysis module, configured to perform spectrum analysis on the transient voltage response, identify a valley point and a peak point, and extract a valley frequency corresponding to the valley point and a peak frequency corresponding to the peak point; and
a parameter calculation module, configured to calculate a stray parameter of the CVT according to the valley frequency and/or the peak frequency, to obtain a frequency characteristic measurement result.

5. A computer terminal, comprising a memory, a processor, and a computer program stored in the memory and executable on the processor, wherein the processor, when executing the program, implements the method for measuring a frequency characteristic of a capacitor voltage transformer according to claim 1.

6. The computer terminal according to claim 5, wherein the transient voltage is any one of a voltage sag process voltage, a voltage swell process voltage, a switching overvoltage, and a lightning overvoltage.

7. The computer terminal according to claim 5, wherein the stray parameter comprises the stray capacitance of the compensation reactor, the ground stray capacitance of the primary winding of the intermediate transformer, the ground stray capacitance of the secondary winding of the intermediate transformer, and the distributed capacitance between the primary and secondary windings.
